(19) United States
(12) Patent Application Publication
(10) Pub. No.: US 2015/0270334 A1
(43) Pub. Date: Sep. 24, 2015

(54) SEMICONDUCTOR DEVICE

(71) Applicant: Sanken Electric Co., Ltd., Niiza-Shi (JP)

(72) Inventor: Shuichi OKUBO, Iruma-Gun (JP)

(21) Appl. No.: 14/656,803

(22) Filed: Mar. 13, 2015

(30) Foreign Application Priority Data
Mar. 24, 2014 (JP) 2014-060056

(51) Int. Cl. H01L 29/06

(52) U.S. Cl. CPC H01L 29/0619

(57) ABSTRACT

A semiconductor device is provided, comprising a semiconductor base of a first conductivity type having a main surface, an element region arranged in the main surface; and a peripheral region surrounding the element region, the peripheral region comprising a field limiting ring region including a peripheral semiconductor region of a second conductivity type surrounding the element region in the main surface of the semiconductor base, the field limiting ring region including a groove formed in the peripheral semiconductor region, the groove extending in a film-thickness direction from an upper surface of the peripheral semiconductor region. As seen along a direction from the element region toward an outer edge of the peripheral region, a center position of the groove is closer to the element region than a center position of the peripheral semiconductor region.

### CROSS REFERENCE TO RELATED APPLICATIONS

This application claims priority based on 35 USC 119 from prior Japanese Patent Application No. 2014-060056 filed on Mar. 24, 2014, entitled “SEMICONDUCTOR DEVICE”, the entire contents of which are hereby incorporated by reference.

### BACKGROUND

The disclosure relates to a semiconductor device with a structure formed therein to improve a breakdown voltage.

In order to improve a breakdown voltage of a semiconductor device, a structure is adopted, in which a field limiting ring (FLR) is arranged in a peripheral region around an element region having a semiconductor element formed therein. The FLR relaxes electric field concentration that occurs around the element region, thereby improving the breakdown voltage of the semiconductor device (see, for example, Japanese Patent Application Publication No. 2013-168549 (Patent Document 1)).

### SUMMARY

In order to improve a breakdown voltage of a semiconductor device, an FLR having a certain depth needs to be formed. However, high energy ion implantation is required to form such a deep FLR, leading to an increase in manufacturing cost. On the other hand, low implantation energy results in an insufficient depth of the FLR. As a result, a breakdown voltage cannot be ensured due to insufficient spread of a depletion layer.

According to an aspect of the invention, a semiconductor device is provided, including: (i) a semiconductor base of a first conductivity type with a main surface on which an element region and a peripheral region surrounding the element region are defined; and (ii) an FLR region including a peripheral semiconductor region of a second conductivity type arranged surrounding the element region in an upper part of the semiconductor base in the peripheral region, the FLR region including a groove formed in the peripheral semiconductor region, the groove extending in a film-thickness direction from an upper surface of the peripheral semiconductor region, wherein, when seen along a direction from the element region toward an outer edge of the peripheral region, a center position of the groove is closer to the element region than a center position of the peripheral semiconductor region in the peripheral semiconductor region.

### BRIEF DESCRIPTION OF THE DRAWINGS

FIG. 1 is a schematic cross-sectional view illustrating a configuration of a semiconductor device according to an embodiment.

FIG. 2 is a schematic view illustrating a structure of an FLR in the semiconductor device according to the embodiment.

FIG. 3 is a schematic view illustrating a structure of an FLR of a comparative example.

FIG. 4 is a schematic cross-sectional view explaining a semiconductor device of the comparative example.

FIG. 5 is a schematic cross-sectional view explaining a semiconductor device of another comparative example.

FIG. 6 is a schematic cross-sectional view (Part 1) explaining a method of forming the FLR in the semiconductor device according to the embodiment.

FIG. 7 is a schematic cross-sectional view (Part 2) explaining the method of forming the FLR in the semiconductor device according to the embodiment.

FIG. 8 is a schematic cross-sectional view (Part 3) explaining the method of forming the FLR in the semiconductor device according to the embodiment.

FIG. 9 is a schematic view illustrating another structure of the FLR in the semiconductor device according to the embodiment.

FIG. 10 is a schematic view illustrating a structure of an FLR in a semiconductor device according to another embodiment.

FIG. 11 is a schematic view illustrating another structure of an FLR in a semiconductor device according to another embodiment.

### DETAILED DESCRIPTION OF EMBODIMENTS

Next, with reference to the drawings, embodiments are described. In the following description of the drawings, the same or similar parts are denoted by the same or similar reference numerals. However, it should be noted that the drawings are conceptual and ratios of thicknesses of respective layers and the like are different from actual ones. Therefore, specific thicknesses and dimensions should be determined by taking into consideration the following description. Moreover, among the drawings, there are included portions in which dimensional relationships and ratios are different from each other.

The following embodiments illustrate devices and methods for embodying a technical idea of the invention. Materials, shapes, structures, arrangements and the like of constituent components of the embodiments do not limit the invention. Various changes can be added to the embodiments of the invention within the scope of claims.

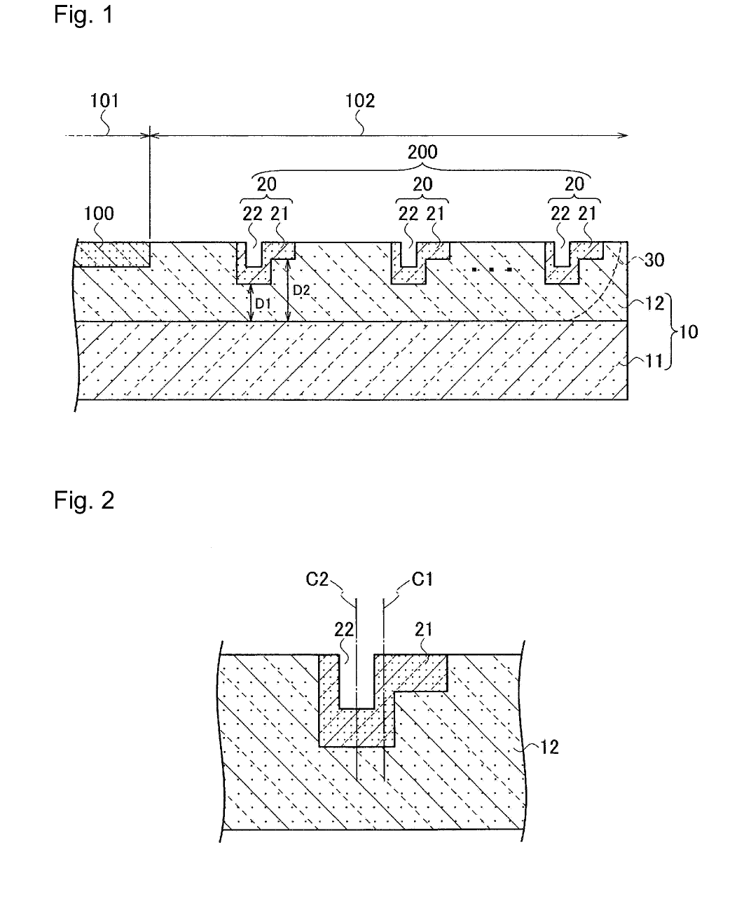

As illustrated in FIG. 1, semiconductor device 1 according to the embodiment includes: semiconductor base 10 of a first conductivity type with a main surface on which element region 101 and peripheral region 102 surrounding element region 101 are defined; and FLR region 200 arranged surrounding element region 101 in peripheral region 102. Although not illustrated, various semiconductor elements, such as a transistor and a diode, are arranged in element region 101.

Semiconductor base 10 includes semiconductor substrate and semiconductor layer 12 arranged on semiconductor substrate 11. Semiconductor substrate 11 is a silicon (Si) substrate, a silicon carbide (SiC) substrate or the like, for example. Semiconductor base 10 has a structure in which semiconductor layer 12 of the first conductivity type is epitaxially grown on semiconductor substrate 11 of the first conductivity type, for example.

FLR region 200 includes peripheral semiconductor regions 21 of a second conductivity type, which are arranged spaced apart from each other in an upper part of semiconductor layer 12. In each of peripheral semiconductor regions 21, groove 22 is formed, which extends in a film-thickness direction from an upper surface of peripheral semiconductor region 21. As illustrated in FIG. 1, the entire groove 22 is surrounded by peripheral semiconductor region 21.

Note that the first conductivity type and the second conductivity type are opposite to each other. More specifically, the second conductivity type is a p type if the first conductivity type is an n type, and the second conductivity type is the n type if the first conductivity type is the p type. The following description is given of, as an example, the case where the first conductivity type is the n type and the second conductivity type is the p type. In other words, it is assumed that semiconductor base 10 has a structure in which low concentration n-type semiconductor layer 12 is formed on high concentration n-type semiconductor substrate 11.

In FLR region 200, p-type peripheral semiconductor regions 21 are selectively formed in a part of the upper part of semiconductor layer 12 while being spaced apart from each other and surrounding element region 101. In semiconductor device 1, peripheral semiconductor regions 21 formed in peripheral region 102 and in an electrically floating state function as FLRs 20.

As illustrated in FIG. 1, groove 22 is formed on a side of peripheral semiconductor region 21 closer to the element region (hereinafter referred to as the “element region side”). More specifically, as illustrated in FIG. 2, when seen along a direction from element region 101 toward an outer edge of peripheral region 102, groove 22 is formed such that center position C2 of groove 22 is closer to element region 101 than center position C1 of peripheral semiconductor region 21.

Thus, as illustrated in FIG. 1, there is a difference in depth of peripheral semiconductor region 21. Specifically, the position of a bottom surface of peripheral semiconductor region 21 is closer to an upper surface of semiconductor substrate 11 in a region where groove 22 is formed than in a region closer to the outer edge of peripheral region 102 than groove 22. Assuming that a distance between the bottom surface of peripheral semiconductor region 21 and the upper surface of semiconductor substrate 11 below the bottom of groove 22 is D1 and a distance between the bottom surface of peripheral semiconductor region 21 and the upper surface of semiconductor substrate 11 in the region closer to the outer edge of peripheral region 102 than groove 22, D1<D2 is established.

During a reverse bias, depletion layer 30 spreads within semiconductor layer 12, and the FLRs 20 are sequentially connected by the depletion layer from the element region 101 side toward the outer edge of peripheral region 102. In semiconductor device 1, peripheral semiconductor region 21 in FLR 20 is provided with a difference in level in the film-thickness direction, such that peripheral semiconductor region 21 is deeper on the element region side and becomes shallower toward the outer edge. Therefore, depletion layer 30 spreading within semiconductor layer 12 has a smooth edge. As a result, electric field concentration can be relaxed more effectively.

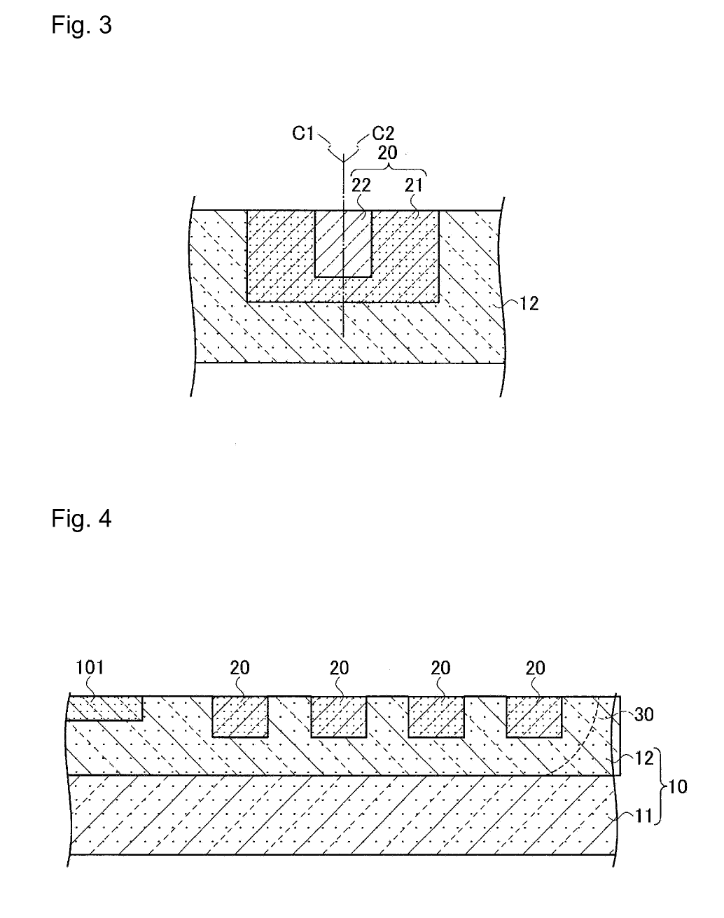

On the other hand, as illustrated in FIG. 3, for example, when groove 22 is formed around the center of peripheral semiconductor region 21, the depth of FLR 20 does not get smaller from the element region side toward the outer edge. Therefore, it is effective in improving a breakdown voltage to form groove 22 such that center position C2 of groove 22 is closer to element region 101 than center position C1 of peripheral semiconductor region 21, as in semiconductor device 1 illustrated in FIG. 1.

Meanwhile, when no groove 22 is formed in FLR 20, FLR 20 needs to be formed deep as illustrated in FIG. 4, in order for depletion layer 30 to spread within semiconductor layer 12. However, high energy ion implantation is required to form deep FLR 20, leading to an increase in manufacturing cost.

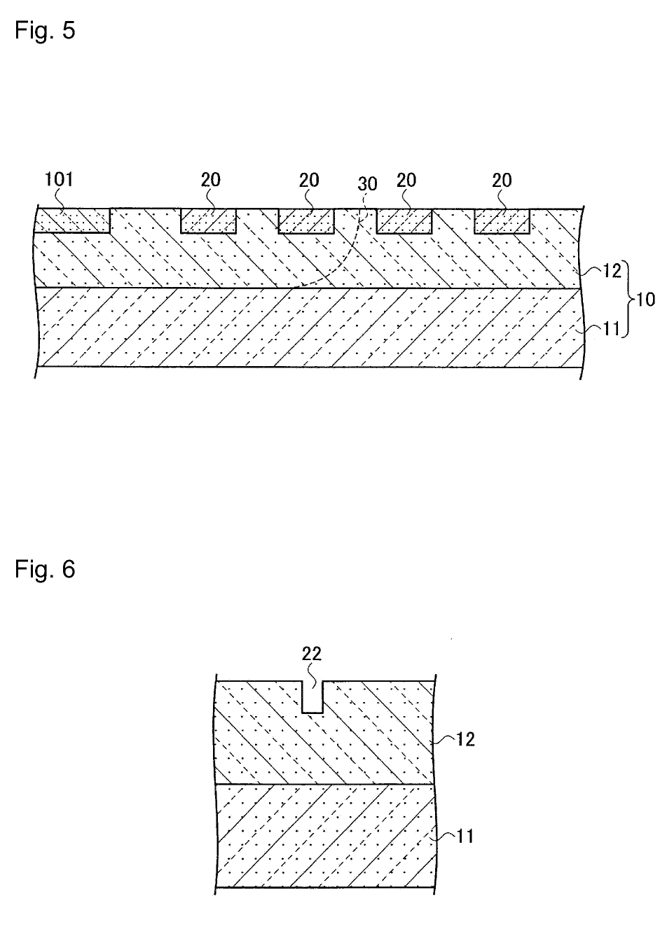

On the other hand, low implantation energy results in an insufficient depth of FLR 20, and thus, as illustrated in FIG. 5, depletion layer 30 does not spread sufficiently. As a result, a breakdown voltage cannot be ensured.

Meanwhile, in semiconductor device 1 illustrated in FIG. 1, impurity ions are implanted into semiconductor layer 12 from the bottom surface of groove 22 as described later. Thus, even with low energy ion implantation, FLR 20 can be formed, which is deep enough for depletion layer 30 to spread sufficiently while connecting FLRs 20.

An example of a method of forming FLR 20 in semiconductor device 1 is described below. Note that, as a matter of course, the method of forming the FLR described below is an example, and the FLR can be realized using various other formation methods including the modified example.

First, as illustrated in FIG. 6, groove 22 is formed at a predetermined position in the upper part of semiconductor layer 12. The position of groove 22 is set such that the center of groove 22 is closer to element region 101 than the center of peripheral semiconductor region 21 within a region where peripheral semiconductor region 21 is to be formed.

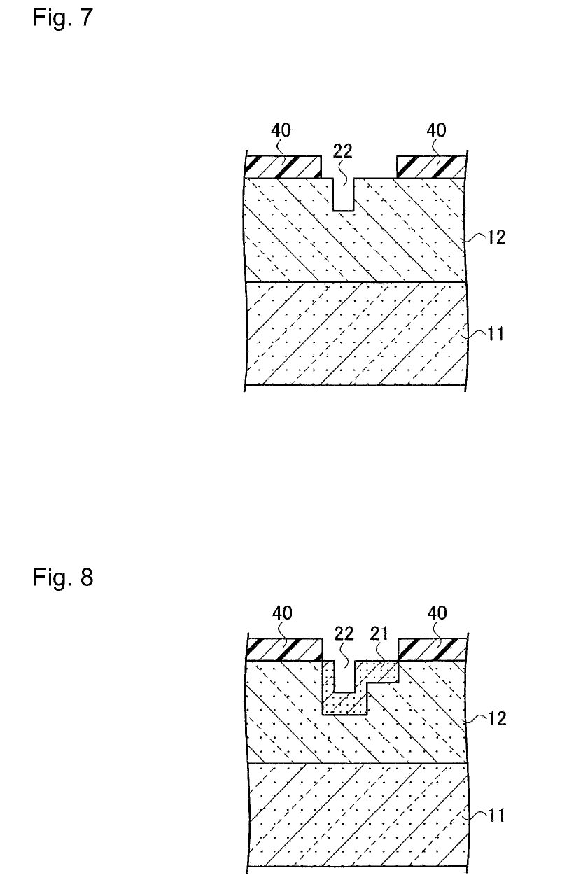

Next, a photoresist film is formed on semiconductor layer 12. Then, the photoresist film is patterned using a photolithography technology. Specifically, as illustrated in FIG. 7, mask 40 is formed in a region other than the region where peripheral semiconductor region 21 is to be formed.

Thereafter, ion implantation using mask 40 is performed to form peripheral semiconductor region 21 as illustrated in FIG. 8. Note that, when semiconductor layer 12 is the n type, aluminum (Al) ions or the like, for example, are implanted into semiconductor layer 12 as p-type impurities. On the other hand, when semiconductor layer 12 is the p type, phosphorus (P) ions or the like, for example, are implanted into semiconductor layer 12 as n-type impurities.

As described above, the ion implantation to form peripheral semiconductor region 21 is performed after groove 22 is formed. Thus, the position of the bottom surface of peripheral semiconductor region 21 is closer to the upper surface of semiconductor substrate 11 in the region below the bottom of groove 22 than in the region where groove 22 is not formed. As a result, FLR 20 provided with a difference in level in the film-thickness direction is formed such that the FLR is deeper on the element region side and becomes shallower toward the outer edge. Moreover, since groove 22 is formed, the number of ion implantations to form FLR 20 up to a predetermined depth can also be reduced.

Meanwhile, the entire groove 22 is covered with peripheral semiconductor region 21 so as not to come into direct contact with semiconductor layer 12. More specifically, apart of peripheral semiconductor region 21 is arranged also between element region 101 and a wall surface of groove 22 on the element region side. This is because direct contact between the depletion layer and groove 22 causes a problem such as a leak current.

Note that a step of forming groove 22 is arbitrary. For example, when semiconductor substrate 11 is an SiC substrate, groove 22 may be simultaneously formed in a step of forming an alignment mark on the SiC substrate.

According to the study conducted by the inventors, effective arrangement of FLR 20 to improve a breakdown voltage is as follows. The depth of groove 22 may be about 10% to 40% of the thickness of semiconductor layer 12. That is, the depth of groove 22 may be about 10%, 15%, 20%, 25%, 30%, 35%, 40% of the thickness of semiconductor layer 12. Also, a distance between adjacent peripheral semiconductor regions 21 is about 10% to 20% of the thickness of semiconductor layer 12. That is, a distance between adjacent peripheral semiconductor regions 21 is about 10%, 11%, 12%, 13%, 14%, 15%, 16%, 17%, 18%, 19%, or 20% of the thickness of semiconductor layer 12.

As described above, in semiconductor device 1 according to the embodiment, groove 22 formed in FLR 20 suppresses the ion implantation energy during the FLR formation. Moreover, by forming groove 22 closer to the element region side than the center of FLR 20, FLR 20 is provided with a difference in thickness in the film-thickness direction such that the FLR becomes shallower toward the outer edge from the element region 101 side. Thus, depletion layer 30 spreading within semiconductor layer 12 has a smooth edge. As a result, electric field concentration can be relaxed more effectively. As described above, according to semiconductor device 1 illustrated in FIG. 1, a semiconductor device can be provided, which has a breakdown voltage improved while suppressing an increase in manufacturing cost.

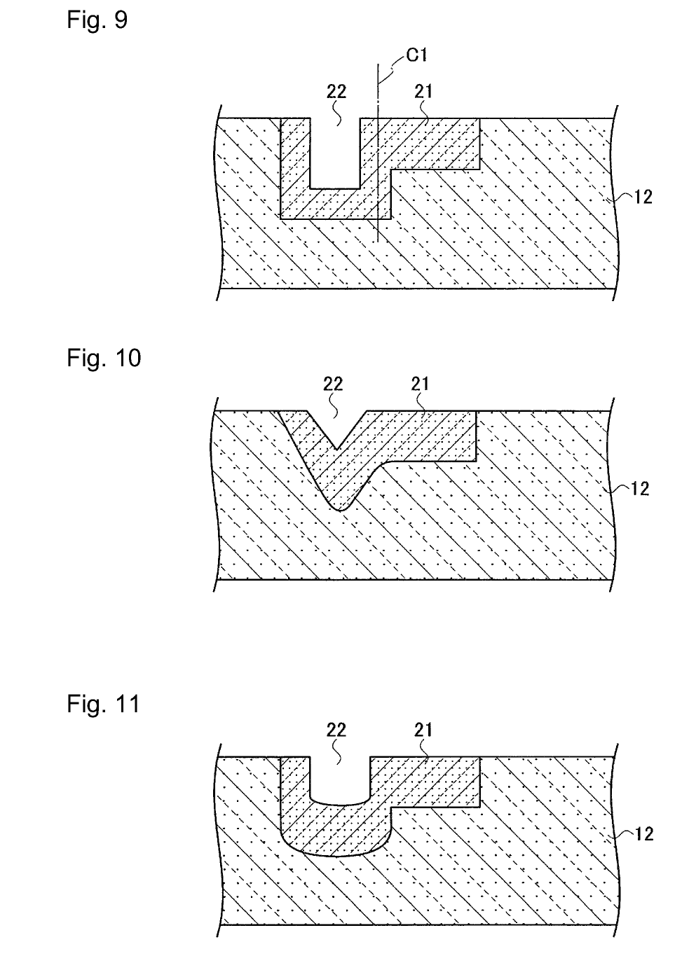

Note that, as illustrated in FIG. 9, groove 22 may be formed such that the entire groove 22 is closer to element region 101 than the center position of peripheral semiconductor region 21. Thus, it is further ensured that FLR 20 is shallower from the element region 101 side toward the outer edge.

### Other Embodiments

It should be understood that the invention is not limited to the description and drawings, which constitute apart of this disclosure. From this disclosure, various alternative embodiments, examples and operational technologies will become apparent to those skilled in the art.

Although the above description is given of the case where the cross-section of groove 22 along the film-thickness direction has a rectangular shape, the groove may have another shape. For example, the groove may have a V-shape as illustrated in FIG. 10. Alternatively, the corners of the bottom of groove 22 may be curved and rounded as illustrated in FIG. 11. In the case of groove 22 having the shape illustrated in FIG. 11, for example, electric field concentration is relaxed at the corners. Thus, the breakdown voltage of semiconductor device 1 is further improved. The structure illustrated in FIG. 11 is particularly effective in rounding the corners of FLR 20 in the case of the SiC substrate having difficulty in adjusting impurity distribution by thermal diffusion after ion implantation.

In this way, embodiments described above provide semiconductor devices having a breakdown voltage improved while suppressing an increase in manufacturing cost.

As described above, the invention includes various embodiments and the like which are not described herein, as a matter of course. Therefore, a technological scope of the invention is defined only by items specific to the invention according to claims pertinent based on the foregoing description.

1. A semiconductor device comprising:
a semiconductor base of a first conductivity type having a main surface,
an element region arranged in the main surface; and
a peripheral region surrounding the element region, the peripheral region comprising a field limiting ring region including a peripheral semiconductor region of a second conductivity type surrounding the element region in the main surface of the semiconductor base, the field limiting ring region including a groove formed in the peripheral semiconductor region, the groove extending in a film-thickness direction from an upper surface of the peripheral semiconductor region, wherein,
as seen along a direction from the element region toward an outer edge of the peripheral region, a center position of the groove is closer to the element region than a center position of the peripheral semiconductor region.

2. The semiconductor device according to claim 1, wherein
the peripheral semiconductor region is provided with a difference in level in the film-thickness direction, such that the peripheral semiconductor region is deeper on the side closer to the element region and becomes shallower toward an outer edge of the peripheral region.

3. The semiconductor device according to claim 1, wherein
the entire groove is closer to the element region than the center position of the peripheral semiconductor region.

4. The semiconductor device according to claim 1, wherein
a portion of the peripheral semiconductor region is arranged between the element region and a wall surface of the groove on the side closer to the element region.

5. The semiconductor device according to claim 1, wherein
corners of the bottom of the groove are rounded.

6. The semiconductor device according to claim 1, wherein the semiconductor base comprises a semiconductor substrate and a semiconductor layer, wherein a depth of the groove pertains to about 10% to 40% of the thickness of the semiconductor layer.

7. The semiconductor device according to claim 1, wherein the semiconductor base comprises a semiconductor substrate and a semiconductor layer, wherein
the field limiting ring region includes a plurality of peripheral semiconductor regions of a second conductivity type surrounding the element region in the main surface of the semiconductor base, wherein
a distance between adjacent peripheral semiconductor regions is about 10% to 20% of the thickness of semiconductor layer.

8. The semiconductor device according to claim 2, wherein
the entire groove is closer to the element region than the center position of the peripheral semiconductor region.

9. The semiconductor device according to claim 2, wherein
a portion of the peripheral semiconductor region is arranged between the element region and a wall surface of the groove on the side closer to the element region.

10. The semiconductor device according to claim 2, wherein
corners of the bottom of the groove are rounded.
